(19) United States
(12) Patent Application Publication
(10) Pub. No.: US 2025/0076408 A1
(43) Pub. Date: Mar. 6, 2025

(54) DISTRIBUTION BOARD WITH WIRELESS LEAKAGE AND OVERHEATING ALARM FUNCTIONS ENABLING EMERGENCY SITUATION TO BE HANDLED BY APPLYING NON-CONTACT ENERGY HARVESTING LEAKAGE CURRENT AND TEMPERATURE MONITORING TECHNOLOGY

(71) Applicant: NASAN ELECTRIC INDUSTRIES CO., LTD, Gyeongsangnam-do (KR)

(72) Inventors: Jong Hoon BAE, Gyeongsangnam-do (KR); Han Yeul AN, Gyeongsangnam-do (KR)

(73) Assignee: NASAN ELECTRIC INDUSTRIES CO., LTD, Gyeongsangnam-do (KR)

(21) Appl. No.: 18/723,868

(22) PCT Filed: Dec. 14, 2022
(86) PCT No.: PCT/KR2022/020370

§ 371 Date: Jun. 25, 2024

(30) Foreign Application Priority Data
Jan. 13, 2022 (KR) 10-2022-0005078

(51) Int. Cl. G01R 31/52; G01K 3/00; G01R 31/58; H02J 9/06; H02J 50/00

(52) U.S. Cl. CPC G01R 31/52; G01K 3/005; G01R 31/58; H02J 9/06; H02J 50/001

(57) ABSTRACT

According to the present invention, a distribution board with wireless leakage and overheating alarm functions enabling an emergency situation to be handled by applying a non-contact energy harvesting leakage current and temperature monitoring technology comprises: a distribution board body for receiving and distributing power; an energy harvesting unit for harvesting energy required for operation by using electromotive force induced in a main energy harvesting coil from among energy harvesting coils provided in the vicinity of each of conductors to be monitored; a leakage current monitoring unit for monitoring, in a non-contact manner, a leakage current flowing in a zero-phase current transformer coil provided to encompass, in a non-contact manner, the plurality of conductors to be monitored; a wireless transmission/reception unit for receiving the value of the leakage current from the leakage current monitoring unit, and converting the received value of the leakage current into a low-power wireless signal and transmitting same to a terminal; and an emergency situation control unit for harvesting energy required for operation by using electromotive force induced in a sub energy harvesting coil, excluding the main energy harvesting coil, if an emergency situation occurs in which the energy harvesting unit cannot harvest the energy required for operation, and notifying the terminal that the emergency situation has occurred by using the energy harvested from sub energy harvesting coil. According to the present invention, a leakage current can be monitored in a non-contact manner even if a disconnection occurs in one of the conductors to be monitored.

### TECHNICAL FIELD

The present invention relates to a technology for monitoring leakage current of conductors to be monitored, particularly, a distribution board with wireless leakage and overheating alarm function that monitors leakage current of conductors to be monitored using energy harvesting technology without external power supply.

### BACKGROUND ART

In general, distribution boards are installed in factories, heavy industrial plants, subways, petroleum complexes, chemical complexes, steelworks, or the like to distribute main power as unit power that can be used by various power devices while controlling the main power provided from KEPCO. Such distribution boards include at least one main circuit breaker that is installed on a front surface of a base panel and controls the main power, and a plurality of sub circuit breakers that control the unit power. The main circuit breaker and the sub circuit breakers are electrically connected to each other by at least one main busbar and a plurality of sub busbars that provide a line for distributing the main power to the unit power. In this manner, a busbar of the distribution boards which includes a main busbar and sub busbars has a metal plate shape with a large surface area to be excellent in heat dissipation and reduce the amount of generated heat due to reduction in impedance, thereby providing, as a replacement for a power cable, a stable line for distributing main power to unit power.

Here, the amount of current flowing in the busbar changes depending on load variations of a power device that uses unit power on a receiver side, and a temperature of the busbar rises if the amount of current increases or a load current is excessive. The temperature rise of the busbar has a significant impact on the stability of power supply equipment, and thus needs to be monitored. In addition, in a case where leakage current is generated from the busbar, the leakage current can have a severe impact on power receiving/distributing equipment, and thus an accurate monitoring system needs to be provided. 1,673 electric shock accidents occurred for the last three years and resulted in the death toll at 74, and the third most common cause thereof is electric leakage.

In order to prevent accidents in advance by monitoring leakage current status of power receiving/distributing equipment, inspectors check conditions of electric leakage in general electric equipment every one to three years with personal visits in accordance with Article 66 of Electric Utility Act of Korean law. However, the electric equipment is not maintained in the same condition as that at the time of inspection, and thus it is difficult to predict signs of accidents.

In a case where wireless sensors are used to monitor leakage current, power needs to be supplied to the sensors and transmission/reception modules. Hence, each module needs to have an independent power source such as a dry cell or a battery, which needs to be replaced periodically. In this case, the power source of the dry cell or the battery needs to be replaced after power is cut off in order to prevent safety accidents, and thus a problem of operational downtime arises.

Online-based wireless electric leakage alarms has been recently developed, but they are not widely used since the wireless electric leakage alarms use secondary sides of circuit breakers as power of a wireless transmitter and can have an impact on stability of an electrical system.

Meanwhile, in order to solve these problems, devices that convert magnetic energy into electrical energy by using a coil and monitor status wirelessly using the electrical energy are developed.

Korean Patent Application No. 10-2014-0010309 (Title of the Invention: “ENERGY HARVESTING METHOD AND APPARATUS USING LEAKAGE POWER”, Application Date: Jan. 28, 2014) discloses a technology that can collect energy and transmit the energy to a battery by applying an energy harvesting technology. This method enables the leakage current to charge the capacitor through an electrode when a contact portion is connected to an electronic device that generate leakage current so the electrical energy of a capacitor is transmitted to a battery by an interface device connecting the capacitor and the battery when the capacitor has a charged voltage above a certain value.

Energy harvesting technologies in the related art are advantageous in that additional power supply is not required to monitor status information such as the leakage current.

However, while the energy harvesting technologies in the related art can detect, without additional power supply, events in which leakage current is generated while conductors to be monitored normally operate, they cannot harvest energy while a phase current does not flow to the conductors to be monitored at all. Therefore, in the case of serious accidents in which conductors to be monitored do not normally operate, for example, a conductor having one phase of the RST phases is disconnected, a severe problem arises in that such state cannot be monitored.

Therefore, there is an urgent demand for a technology that can monitor leakage current in a non-contact manner even if a disconnection occurs in one of the conductors to be monitored in which phase currents flow.

In addition, there is an urgent demand for a technology that can actively detect a case of a disturbance in a balance between phase currents by comparing energies harvested from respective conductors to be monitored in which phase currents flow.

### SUMMARY OF INVENTION

### Technical Problem

An object of the present invention is to provide a distribution board that can monitor leakage current in a non-contact manner even if a disconnection occurs in one of the conductors to be monitored in which phase currents flow.

In addition, another object of the present invention is to provide a technology that can actively detect a case of a disturbance in a balance between phase currents by comparing energies harvested from respective conductors to be monitored in which phase currents flow.

### Solution to Problem

One aspect of the present invention to achieve the above objects relates to a distribution board with wireless leakage and overheating alarm functions enabling an emergency ssituation to be handled by applying a non-contact energy harvesting leakage current and temperature monitoring technology. According to the present invention, there is provided a non-contact energy harvesting leakage current monitoring device in a distribution board, comprising: a distribution board main body for receiving and distributing power; an energy harvesting unit for harvesting energy required for operation by using electromotive force induced in a main energy harvesting coil from among energy harvesting coils provided in a vicinity of each of a plurality conductors to be monitored in which phase currents flow; a leakage current monitoring unit for receiving the energy harvested by the energy harvesting unit and monitoring, in a non-contact manner, a leakage current flowing in a zero-phase current transformer coil provided to encompass, in a non-contact manner, the plurality of conductors to be monitored; a wireless transmission/reception unit for receiving the value of the leakage current from the leakage current monitoring unit and converting the received value of the leakage current into a low-power wireless signal and transmitting the low-power wireless signal to a terminal; and an emergency situation control unit for harvesting energy required for operation by using electromotive force induced in a sub energy harvesting coil, excluding the main energy harvesting coil, if an emergency situation occurs in which the energy harvesting unit cannot harvest the energy required for operation, and notifying the terminal that the emergency situation has occurred by using the energy harvested from sub energy harvesting coil. In particular, the emergency situation control unit is further configured for receiving energy required for operation from an emergency power unit if there is no electromotive force induced in both the main energy harvesting coil and the sub energy harvesting coil and notifying the terminal that there is no electromotive force induced in both energy harvesting coils. In addition, the emergency situation control unit is further configured for notifying the terminal that an emergency situation has occurred when energy harvested from the main energy harvesting coil is compared with energy harvested from the sub energy harvesting coil and a difference between the energies is a predetermined value or higher. Preferably, the emergency situation control unit is further configured for cutting off power supplied to the conductors to be monitored if an emergency situation has occurred. The emergency power unit may be a rechargeable battery or a disposable battery, and each of the conductors to be monitored may be a quadrangular busbar or a round cable. In addition, the conductors to be monitored may be provided at any one of a power receiving board, a power distributing board, a cable tray, and an indoor/outdoor transformer and may be either underground cables or overhead power transmission lines.

### Advantageous Effects of Invention

According to the present invention, there is provided a non-contact energy harvesting leakage current monitoring device included in a distribution board that can monitor leakage current in a non-contact manner even if a disconnection occurs in one of the conductors to be monitored in which phase currents flow.

In addition, according to the present invention, it is possible to actively detect a case of a disturbance in a balance between phase currents by comparing energies harvested from respective conductors to be monitored in which phase currents flow.

### BRIEF DESCRIPTION OF DRAWINGS

FIG. 1A is a block diagram schematically illustrating a non-contact energy harvesting leakage current monitoring device included in a distribution board according to the present invention.

FIG. 1B is a flowchart schematically illustrating a method for monitoring leakage current which is executed by the non-contact energy harvesting leakage current monitoring device included in a distribution board according to the present invention.

FIG. 2 is a diagram schematically illustrating an embodiment of the non-contact energy harvesting leakage current monitoring device included in a distribution board according to the present invention.

FIG. 3A and FIG. 3B are diagrams schematically illustrating a structure in which the non-contact energy harvesting leakage current monitoring device included in a distribution board according to the present invention is provided on a quadrangular busbar.

FIG. 4A and FIG. 4B are diagrams schematically illustrating a structure in which the non-contact energy harvesting leakage current monitoring device included in a distribution board according to the present invention is provided on a round cable bar.

FIG. 5 is a block diagram schematically illustrating a system for monitoring leakage current by using harvested energy.

FIG. 6 is a schematic view of a distribution board with wireless leakage and overheating alarm functions enabling an emergency situation to be handled by applying a non-contact energy harvesting leakage current and temperature monitoring technology according to the present invention.

### DESCRIPTION OF EMBODIMENTS

The present invention, operational advantages of the present invention and objects to be achieved by embodiments of the present invention can be fully understood by referring to the accompanying drawings illustrating preferred embodiments of the present invention and the details illustrated in the accompanying drawings.

Hereinafter, the present invention will be described in detail by describing preferred embodiments of the present invention with reference to the accompanying drawings. However, the present invention may have various different embodiments and is not limited to the described embodiments. In order to clearly describe the present invention, parts that are not related to the description are omitted, and the same reference numerals in the drawings represent the same members.

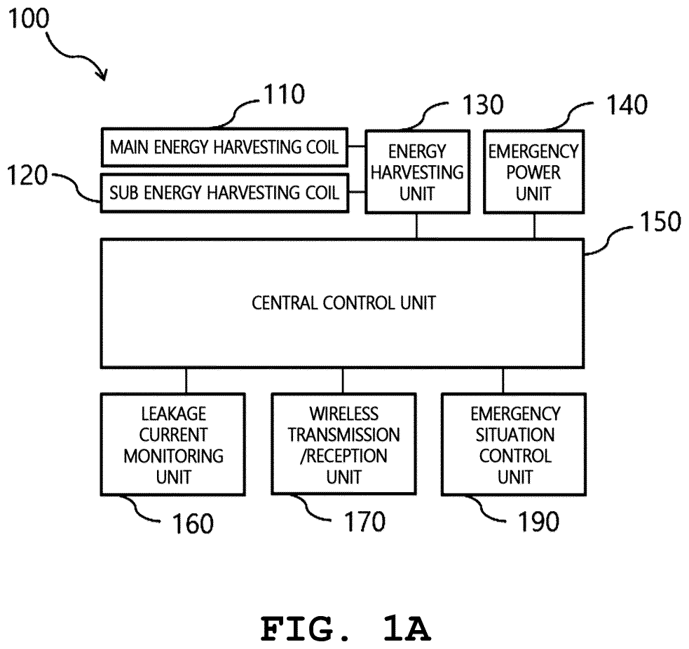

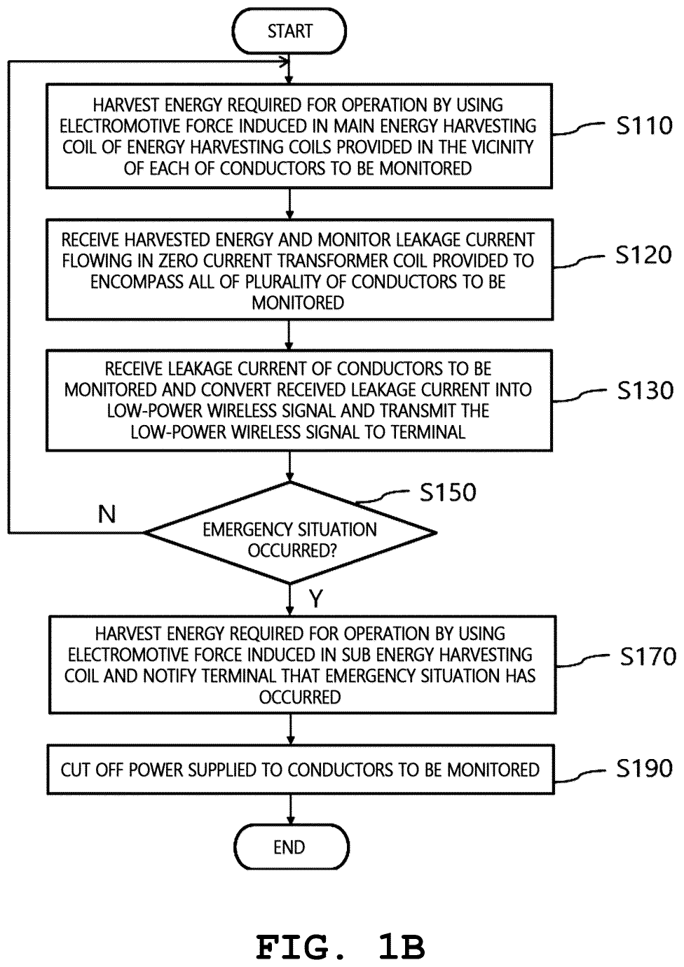

FIG. 1A is a block diagram schematically illustrating a non-contact energy harvesting leakage current monitoring device included in a distribution board according to the present invention.

Referring to FIG. 1A, a non-contact energy harvesting leakage current monitoring device 100 included in a distribution board according to the present invention includes an energy harvesting unit 130, an emergency power unit 140, a central control unit 150, a leakage current monitoring unit 160, a wireless transmission/reception unit 170, and an emergency situation control unit 190. The energy harvesting unit 130 is provided in the vicinity of a main energy harvesting coil 110 and a sub energy harvesting coil 120.

Energy harvesting is a technology that re-harvests discarded energy such as light, heat, or vibration and converts the energy into electrical energy and has been attracting more attention these days as eco-friendliness is on the rise. For example, a variety of energy harvesting systems that supply power by converting various energy sources from photovoltaic elements, piezoelectric elements, and thermal energy converters into electrical energy without external power supply have been proposed. An energy harvesting technology enables leakage power to be stored in a power storage device such as a battery and used as a useful energy source. In particular, the scope of utilization of a sensor which is a basis of the energy harvesting technology is rapidly increasing in the global trend in which big data, smart factories, or the like attract high attention, and in particular, as IoT and ICT develop, sensors utilizing wireless communication are more widely used. Many sensors still use batteries as a power source, but a rapid growth of the energy harvesting technology tends to increase the number of sensors that use, as a main power source, eco-friendly harvested energy which can be used almost permanently regardless of battery life.

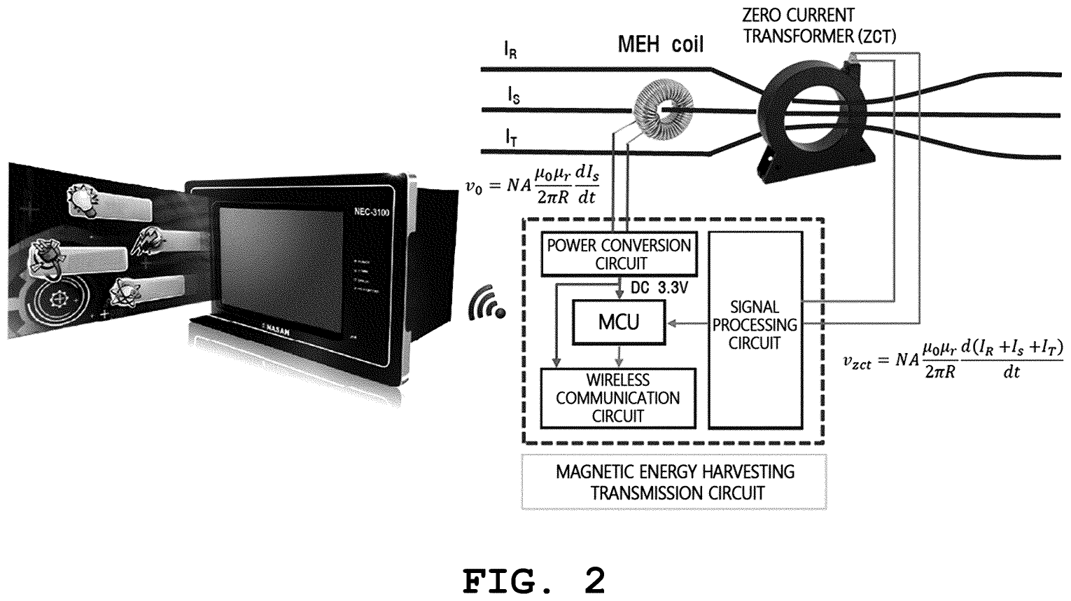

FIG. 2 is a diagram schematically illustrating an embodiment of the non-contact energy harvesting leakage current monitoring device included in a distribution board according to the present invention.

Referring to FIG. 2, it can be found that a power conversion circuit corresponding to an energy harvesting unit harvests energy from an energy harvesting coil provided in the vicinity of an S-phase current of phase currents. However, this is just an example, and the energy harvesting coil can be provided in the vicinity of R-phase and S-phase currents as well as the S-phase current. This will be described in detail in the corresponding section of this specification. Therefore, the repetitive description thereof is omitted to simplify the specification.

The harvested energy is converted into DC voltage through a power conversion circuit, and this voltage is used as an energy source for various elements such as an MCU, a signal processing circuit, and a wireless communication circuit.

It is desirable for the energy harvesting coil to have a configuration for maximizing focused magnetic flux even in an environment where magnetic flux density is reduced. Hence, the energy harvesting coil is preferably made of a Fe—Mn—Zn compound, more specifically a ferrite material having a high permeability of 10,000 or higher.

A ferrite generally refers to a complex oxide containing an iron oxide (Fe₂O₃) as one component and derivatives thereof, particularly, an oxide represented as MO·Fe₂O₃ where M is a divalent metal. In addition, a ferrite core means a magnetic iron core made of ferrite and generally has characteristics of high magnetic permeability and low conductivity.

Therefore, when the energy harvesting coil is manufactured using a ferrite material having high permeability, the magnetic flux focusing performance can be improved, and the non-contact energy harvesting leakage current monitoring device 100 included in a distribution board can be lightweight.

Referring to FIG. 1A again, the energy harvesting unit 130 of the present invention harvests energy from the main energy harvesting coil 110 and the sub energy harvesting coil 120. The main energy harvesting coil 110 and the sub energy harvesting coil 120 may be any coil in which a phase current flows.

In general, energy harvesting coils can harvest energy even when the energy harvesting coils are not provided in the vicinity of all phase currents but are provided in the vicinity of any one of busbars in which phase currents flow. However, in the present invention, the energy harvesting coils are provided in the vicinity of at least two phase currents. That is, the main energy harvesting coil 110 is provided in the vicinity of one of the conductors to be monitored in which a phase current flows, and the sub energy harvesting coil 120 is provided in the vicinity of the rest of the conductors to be monitored. For example, in a case where the phase currents have RST phases, and the main energy harvesting coil 110 is provided in the vicinity of the R-phase current, the sub energy harvesting coil 120 may be provided in the vicinity of at least one of the S-phase and T-phase currents.

Providing two or more energy harvesting coils in this manner has the following advantages.

First, it is possible to harvest more energy by adding up energy harvested from the individual energy harvesting coils.

Second, abnormal conditions occurring in conductors to be monitored can be more accurately monitored by comparing the energies harvested from the respective energy harvesting coils. In a normal condition, the individual energy harvesting coils have to harvest the same amount of energy, and thus a case where the amount of energy obtained from the individual energy harvesting coils is larger than a predetermined value can be determined as an emergency situation.

Third, if an emergency situation such as disconnection in any one of the conductors to be monitored or contamination of the conductors to be monitored occurs, it is not possible to harvest energy from an energy harvesting coil provided in the vicinity of the corresponding conductor any more. Hence, despite such a serious emergency situation, there is no energy for functional units to notify a terminal of this situation through wireless communication. However, when the energy harvesting coils are provided in the vicinity of multiple conductors to be monitored, it is possible to actively cope with such an emergency situation because energy can still be harvested from the other conductors capable of harvesting energy.

When the energy harvesting unit 130 harvests energy required for operation, the leakage current monitoring unit 160 receives the harvested energy and monitors, in a non-contact manner, leakage current flowing in a zero current transformer coil provided to encompass a plurality of conductors to be monitored in a non-contact manner.

A zero current transformer (ZCT) is a transformer obtained by winding a coil in which three phase wires of a three-phase circuit pass through a primary side, and a secondary side is evenly distributed around an iron core. The ZCT refers to a transformer that is to obtain, as an output, a secondary current corresponding to a vector sum of three-phase currents, that is, three times a zero-phase current. When a zero-phase current is obtained using the zero current transformer, errors due to differences in characteristics of an iron core are reduced, and thus it is suitable for high-sensitivity ground fault protection. The zero current transformers can mainly be used to detect a ground fault in a distribution line of an ungrounded system and can also be used to detect a zero-phase current of a wireless leakage alarm in a non-contact manner.

In general, in order for the zero current transformer to operate stably, it is desirable to dispose the zero current transformer to be magnetically balanced when passing through the conductors to be monitored at the primary side. Otherwise, magnetic imbalance can occur and cause malfunction. In a case where another line passes around the zero current transformer, a signal can be distorted. Hence, it is desirable to beware of signal distortion, and it is advisable to use shielded connecting wires for a secondary side connecting wire. Referring to FIG. 2, it can be found that the zero current transformer (ZCT) is provided to encompass all of the phase currents. In this manner, since the zero current transformer (ZCT) is provided in a non-contact manner in the vicinity of the conductors to be monitored, leakage current can be easily monitored without contacting the conductors to be monitored, a maintenance process can be simplified, and worker safety can be guaranteed.

In the present invention, the leakage current monitoring unit 160 detects leakage current by using such a zero current transformer. The leakage current is generated if the three phases do not have the magnetic balance due to a defect in one of the conductors to be monitored in which phase currents flow. Therefore, as described above, the leakage current monitoring unit 160 can detect leakage current by comparing energy harvested by magnetic energy harvesting coils (MEH coils) provided in the vicinity of a plurality of conductors to be monitored. In this case, leakage current monitoring performance can be improved by comparing a monitoring result obtained by the zero current transformer (ZCT) and a result indicating a difference in energy harvested from several phase windings.

That is, the leakage current monitoring unit 160 can use the zero current transformer (ZCT) to transmit a signal to the electric leakage alarm when the sum of currents of the three phases exceeds a set leakage current value, and can issue a warning sound in an operator's terminal.

The wireless transmission/reception unit 170 receives a value of monitored leakage current from the leakage current monitoring unit 160, converts the received value of the leakage current value into a low-power wireless signal, and transmits the low-power wireless signal to the terminal. In particular, if an emergency situation in which the leakage current occurs, the wireless transmission/reception unit 170 can notify an operator of this situation in various ways such as generating a warning sound or the like.

If an emergency situation in which the energy harvesting unit 130 cannot harvest energy required for operation occurs, the emergency situation control unit 190 uses electromotive force induced in the sub energy harvesting coil 120 to harvest energy required for operationand notify the terminal that the emergency situation has occurred by using the energy harvested from the sub energy harvesting coil. In addition, the emergency situation control unit 190 can prevent a major accident in advance by cutting off power supplied to the conductors to be monitored when an emergency situation occurs. To this end, the non-contact energy harvesting leakage current monitoring device 100 included in a distribution board may include a ground fault relay (not illustrated) that cuts off a circuit in the event of electric leakage.

There may be a case where a large event occurred in the conductors to be monitored, and thus it is not possible to harvest energy required for operation from both the main energy harvesting coil 110 and the sub energy harvesting coil 120. Since such an event is not only fatal to the lifespan of the conductors to be monitored, but also can cause a power outage or fire, the events need to be quickly controlled. However, according to the related art, if an abnormality occurs in the conductor to be monitored itself, energy is not harvested, and thus it is not possible to notify the terminal of the important event.

However, according to the present invention, if there is no electromotive force induced in both the main energy harvesting coil and the sub energy harvesting coil, the emergency situation control unit 190 receives energy required for operation from the emergency power unit and notifies the terminal that there is no electromotive force induced in the energy harvesting coils, and thus this event can actively be handled. In such case, the emergency power unit 140 can be a rechargeable battery or a disposable battery.

In the present invention, operation power of the non-contact energy harvesting leakage current monitoring device 100 included in a distribution board is not provided from a battery, but is directly harvested from the conductors to be monitored and used. Hence, no battery is needed under normal operating conditions. A reason why a battery is used in the present invention is to prepare for an emergency situation in which the operation power of the non-contact energy harvesting leakage current monitoring device 100 included in a distribution board cannot be harvested due to an abnormality in all of the conductors to be monitored. Therefore, the battery has limited use only in a serious emergency situation, so little maintenance effort is spent.

The non-contact energy harvesting leakage current monitoring device included in a distribution board as illustrated in FIG. 1A enables leakage magnetic fields generated around a busbar or a cable to be collected and converted to produce power, and the power is supplied to a transmitter such that leakage current in a distribution board can be monitored wirelessly at all times. In addition, by quickly notifying a manager of an alarm when electric leakage occurs, the need for periodic inspections can be eliminated, and electric shocks of workers can be prevented.

FIG. 1B is a flowchart schematically illustrating a method for monitoring leakage current which is executed by the non-contact energy harvesting leakage current monitoring device included in a distribution board according to the present invention.

First of all, energy required for operation is harvested by using electromotive force induced in the main energy harvesting coil of the energy harvesting coils provided in the vicinity of each of a plurality of conductors to be monitored in which phase currents flow (S110). As described above, in the present invention, the energy harvesting coil for harvesting energy required for operation includes the main energy harvesting coil and the sub energy harvesting coil.

When the energy is harvested, the harvested energy is used to monitor, in a non-contact manner, leakage current flowing in the zero current transformer coil that is provided to encompass the plurality of conductors to be monitored in a non-contact manner (S120). During normal operation, theoretically, the vector sum of the phase currents has to be 0. Hence, if the vector sum of the phase currents is not 0 and is detected by the zero current transformer (ZCT), it can be found that a ground fault has occurred. That is, in a case where a ground fault occurs by using the zero current transformer (ZCT), the leakage current can be monitored by detecting a state of a change between a current flowing into a load and a current flowing out of the load.

The leakage current detected by the zero current transformer (ZCT) is received by the wireless transmission/reception unit, and the wireless transmission/reception unit uses the energy obtained from the main energy harvesting coil to convert the leakage current into a low-power wireless signal and transmit the low-power wireless signal to the terminal (S130).

At this time, the method for monitoring energy harvesting energy leakage current in a non-contact manner can be executed to determine whether an emergency situation has occurred and enables the emergency situation to be actively handled (S150). In this specification, an emergency situation or an urgent situation refers to a situation in which leakage current occurs due to an abnormality in at least one of the conductors to be monitored. In particular, according to the present invention, it is possible to harvest energy required for operation from the sub energy harvesting coil if energy cannot be harvested due to a reason such as disconnection of the conductors to be monitored around which the main energy harvesting coil is provided. Further, an emergency situation can be detected more quickly by comparing the energy harvested by the energy harvesting coils provided in the vicinity of respective phase windings.

That is, if it is determined that an emergency situation has occurred, energy required for operation is harvested by using the electromotive force induced in the sub energy harvesting coil other than the main energy harvesting coil, and the occurrence of the emergency situation is notified to the terminal by using the energy harvested from the sub energy harvesting coil (S170). In particular, an accident can be automatically prevented by cutting off the power that is supplied to the conductors to be monitored before manual intervention of the operator (S190).

As described above, the emergency power unit can be a rechargeable battery or a disposable battery, and each of the conductors to be monitored may be a quadrangular busbar or a round cable.

In addition, the quadrangular busbar or the round cable may be installed at a power receiving board, a power distributing board, a cable tray, an indoor/outdoor transformer, and the like such that leakage current can be detected in a non-contact manner. The conductors to be monitored can be either underground cables or overhead power transmission lines.

According to the present invention, it is possible to actively detect a case of a disturbance in a balance between phase currents by comparing energies harvested from respective conductors to be monitored in which phase currents flow.

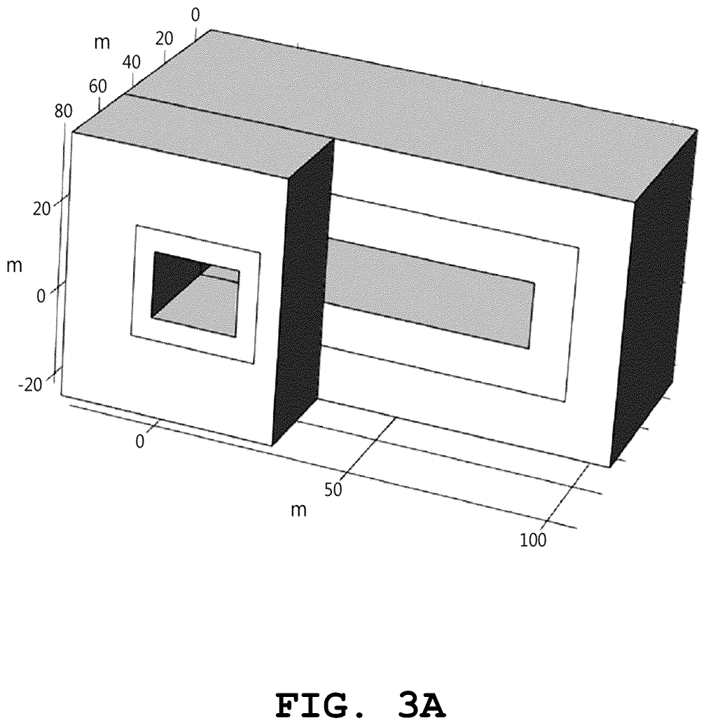

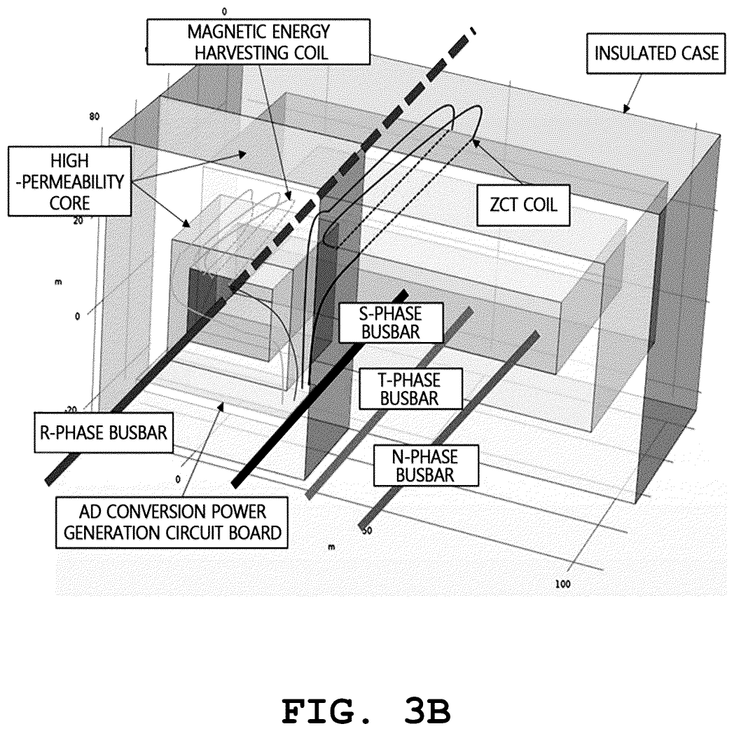

FIG. 3A illustrates the quadrangular busbar at which the non-contact energy harvesting leakage current monitoring device included in a distribution board according to the present invention is provided, and FIG. 3B illustrates a structure in which the non-contact energy harvesting leakage current monitoring device included in a distribution board is provided at the quadrangular busbar.

Referring to FIG. 3B, it can be found that the quadrangular busbar includes an S-phase busbar, a T-phase busbar, an N-phase busbar, and an R-phase busbar, respectively, and the main energy harvesting coil is provided in the vicinity of the R-phase busbar. In this case, the sub energy harvesting coil may be provided in the vicinity of the S-phase busbar and the T-phase busbar. If energy is harvested from the main energy harvesting coil provided in the vicinity of the R-phase busbar, there is no need to harvest energy from the sub energy harvesting coil provided in the vicinity of the S-phase busbar and the T-phase busbar. Hence, the energy harvested from the S-phase busbar and the T-phase busbar is not used to operate the non-contact energy harvesting leakage current monitoring device included in a distribution board, but is used only to detect an emergency situation by being compared with the energy harvested from the R-phase busbar.

The energy harvested from the energy harvesting coils is converted to DC voltage in an AD conversion power generation circuit board.

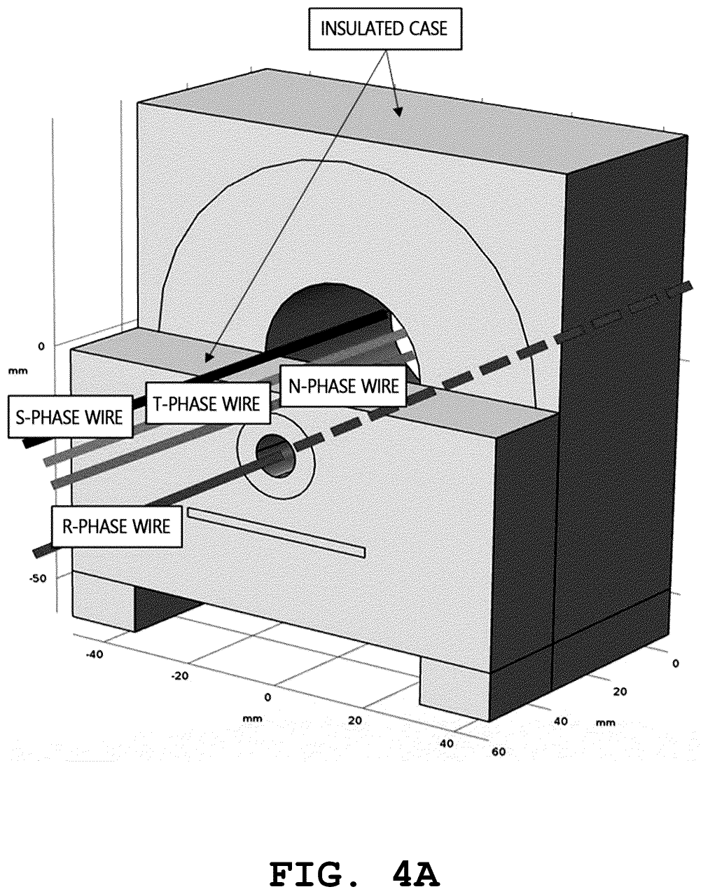

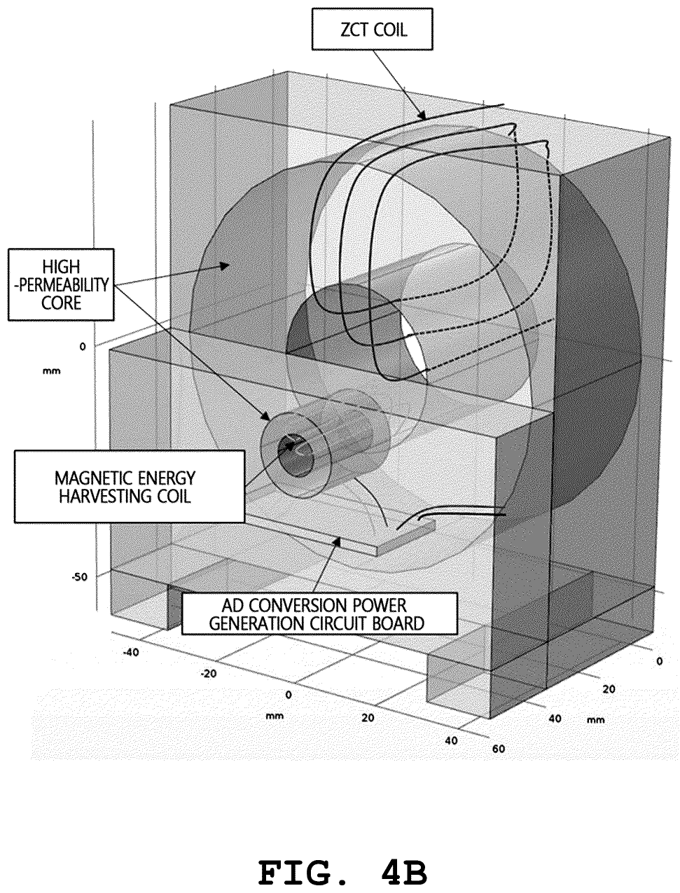

FIG. 4A illustrates a round cable bar at which the non-contact energy harvesting leakage current monitoring device included in a distribution board is provided, and FIG. 4Bb illustrates the energy harvesting coils and the zero current transformer (ZCT) provided in the vicinity of the round cable bar.

As in the case of the quadrangular busbar, the round cable bar includes an S-phase cable bar, a T-phase cable bar, an N-phase cable bar, and an R-phase cable bar, respectively, and the main energy harvesting coil is provided in the vicinity of the R-phase cable bar of the cable bars. In this case, the sub energy harvesting coil can be provided in the vicinity of the S-phase cable bar and the T-phase cable bar. If energy is harvested from the main energy harvesting coil provided in the vicinity of the R-phase cable bar, there is no need to harvest energy from the sub energy harvesting coil provided in the vicinity of the S-phase cable bar and the T-phase cable bar. Hence, the energy harvested from the S-phase cable bar and the T-phase cable bar is not used to operate the non-contact energy harvesting leakage current monitoring device included in a distribution board, but is used only to detect an emergency situation by being compared with the energy harvested from the R-phase cable bar.

The energy harvested from the energy harvesting coils is converted to DC voltage in an AD conversion power generation circuit board.

As can be found in FIGS. 3B and 4B, since the zero current transformer (ZCT) is provided in a form of winding a coil around the conductor to be monitored without contacting the quadrangular busbar or the round cable bar which are the conductors to be monitored, leakage current can be detected in a non-contact manner.

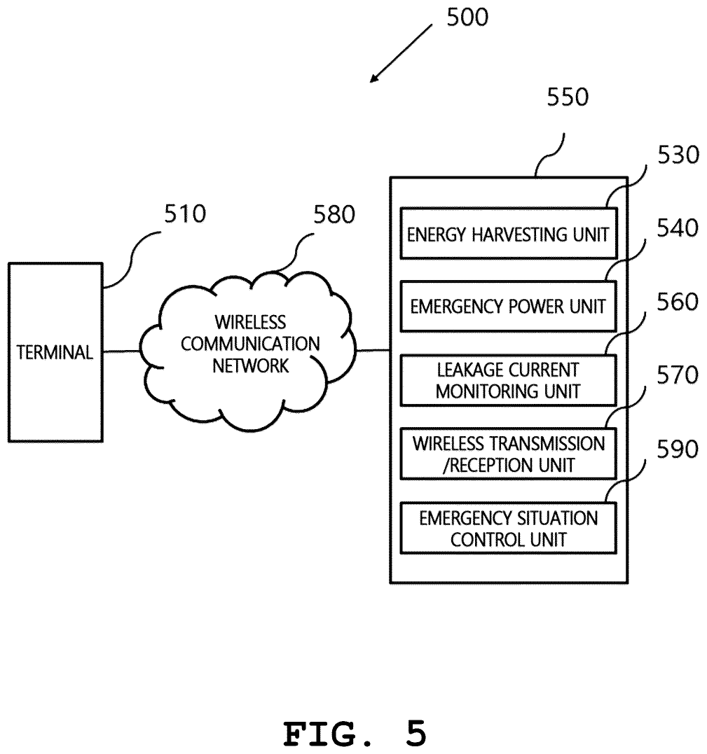

FIG. 5 is a block diagram schematically illustrating a system for monitoring leakage current by using harvested energy.

A non-contact energy harvesting leakage current monitoring system 500 includes a terminal 510 and a non-contact energy harvesting leakage current monitoring device 550 included in a distribution board. The terminal 510 and the non-contact energy harvesting leakage current monitoring device 550 included in a distribution board communicate with each other through a wireless communication network 580.

The non-contact energy harvesting leakage current monitoring device 550 included in a distribution board harvests the energy required for operation from around the conductor to be monitored and detects a value of leakage current of the conductor to be monitored. More specifically, the non-contact energy harvesting leakage current monitoring device 550 included in a distribution board includes an energy harvesting unit 530, an emergency power unit 540, a leakage current monitoring unit 560, a wireless transmission/reception unit 570, and an emergency situation control unit 590.

Configurations and operations of the energy harvesting unit 530, the emergency power unit 540, the leakage current monitoring unit 560, the wireless transmission/reception unit 570, and the emergency situation control unit 590 in FIG. 5 are the same as the configurations and the operations of the energy harvesting unit 130, the emergency power unit 140, the leakage current monitoring unit 160, the wireless transmission/reception unit 170, and the emergency situation control unit 190 in FIG. 1A. Therefore, the repetitive description thereof is omitted to simplify the specification.

The terminal 510 wirelessly receives a value of leakage current transmitted from the leakage current monitoring device 550 and displays the received value of the leakage current.

All known technologies can be used as the wireless communication network 580, and particularly, it is desirable to utilize a next-generation low-power wireless network technology that directly and wirelessly connects a home appliance and a terminal such as a PC, a mobile phone, or a PDA within a range of tens of meters. For example, various technologies such as Bluetooth, ZigBee, ultra-wideband (UWB) communication, and binary CDMA can be utilized.

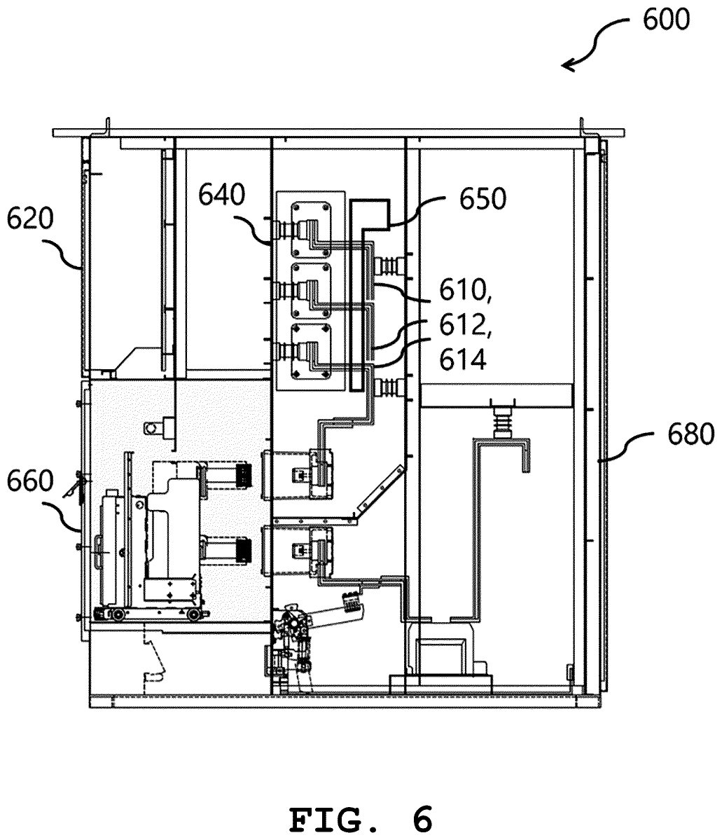

FIG. 6 is a schematic view of a distribution board with wireless leakage and overheating alarm functions enabling an emergency situation to be handled by applying a non-contact energy harvesting leakage current and temperature monitoring technologyaccording to the present invention.

A distribution board 600 in FIG. 6 includes a low-voltage control device chamber 620, a busbar compartment 640, a circuit breaker chamber 660, and a cable compartment and a grounding portion 680, and a non-contact energy harvesting leakage current monitoring device 650 is installed at busbars 610, 612, and 614 of the busbar compartment 640.

As described above, if quadrangular busbars are installed in the busbar compartment 640, the quadrangular busbars include an S-phase busbar, a T-phase busbar, an N-phase busbar, and an R-phase busbar, respectively. A main energy harvesting coil may be provided in the vicinity of one of these busbars 610, 612, and 614, and a sub energy harvesting coil may be provided in the vicinity of the rest of the busbars. If energy is harvested from the main energy harvesting coil provided in the vicinity of the R-phase busbar, there is no need to harvest energy from the sub energy harvesting coil provided in the vicinity of the S-phase busbar and the T-phase busbar. Hence, the energy harvested from the S-phase busbar and the T-phase busbar is not used to operate the non-contact energy harvesting leakage current monitoring device, but is used only to detect an emergency situation by being compared with the energy harvested from the R-phase busbar.

When the distribution board 600 in FIG. 6 is used, leakage current can be monitored in a non-contact manner even if a disconnection occurs in one of the conductors to be monitored, and it is possible to actively detect a case of a disturbance in a balance between phase currents by comparing energies harvested from respective conductors to be monitored.

The present invention has been described with reference to the embodiments illustrated in the drawings, but the embodiments are merely examples, and those skilled in the art will understand that various modifications and other equivalent embodiments can be derived from the embodiments. For example, in the present invention, the main energy harvesting coil is described as being provided in the vicinity of the R-phase busbar, but it is clear that the description does not limit the present invention.

In addition, the method according to the present invention can be implemented as computer-readable codes on computer-readable recording mediums. The computer-readable recording mediums can include all types of recording devices that store data that can be read by a computer system. Examples of computer-readable recording media include a ROM, a RAM, a CD-ROM, a magnetic tape, a floppy disk, an optical data storage device, or the like and can also include a medium that is implemented in a form of a carrier wave (for example, transmission via the Internet). In addition, the computer-readable recording medium can store computer-readable codes that can be executed in a distributed manner by networked distributed computer systems.

In the terms used in this specification, a singular expression should be understood to include a plural expression thereof unless clearly interpreted differently from the context, and the term such as “comprising” should be construed to mean presence of a feature, the number, a step, an operation, a component, a part which are described or a combination thereof and not to exclude a possibility of presence or addition of one or more other features, numbers, steps, operations, components, parts, or combinations thereof. The terms such as “ . . . unit”, “ . . . machine”, “module”, or “block” used in the specification means a unit that processes at least one function or operation, and the unit can be implemented by hardware, software, or a combination of hardware and software.

Hence, the present embodiments and the accompanying drawings in this specification only clearly indicate a part of the technical idea included in the present invention, and it is obvious that modification examples and embodiments which can be easily conceived by those skilled in the art within the scope of the technical ideas included in the specification and the drawings of the present invention are all included in the scope of rights of the present invention.

### INDUSTRIAL APPLICABILITY

The present invention can be used to monitor various transmission and distribution equipment such as a power receiving board, a power distributing board, a cable tray, an indoor/outdoor transformer, and the like.

### REFERENCE SIGNS LIST

100: Non-contact energy harvesting leakage current monitoring device included in distribution board
110: Main energy harvesting coil
120: Sub energy harvesting coil
130, 530: Energy harvesting unit
140, 540: Emergency power unit
150: Central control unit
160, 560: Leakage current monitoring unit
170, 570: Wireless transmission/reception unit
190, 590: Emergency situation control unit

1. A distribution board with wireless leakage and overheating alarm functions enabling an emergency situation to be handled by applying a non-contact energy harvesting leakage current and temperature monitoring technology, comprising:
a distribution board main body for receiving and distributing power;
an energy harvesting unit for harvesting energy required for operation by using electromotive force induced in a main energy harvesting coil from among energy harvesting coils provided in the vicinity of each of a plurality of conductors to be monitored in which phase currents flow;
a leakage current monitoring unit for receiving the energy harvested by the energy harvesting unit and monitoring, in a non-contact manner, a leakage current flowing in a zero-phase current transformer coil provided to encompass, in a non-contact manner, the plurality of conductors to be monitored;
a wireless transmission/reception unit for receiving the value of the leakage current from the leakage current monitoring unit and converting the received value of the leakage current into a low-power wireless signal and transmitting the low-power wireless signal to a terminal; and
an emergency situation control unit for harvesting energy required for operation by using electromotive force induced in a sub energy harvesting coil, excluding the main energy harvesting coil, if an emergency situation occurs in which the energy harvesting unit cannot harvest the energy required for operation and notifying the terminal that the emergency situation has occurred by using the energy harvested from the sub energy harvesting coil.

2. The distribution board with wireless leakage and overheating alarm functions enabling an emergency situation to be handled according to claim 1,
wherein the emergency situation control unit is further configured to receive energy required for operation from an emergency power unit if there is no electromotive force induced in both the main energy harvesting coil and the sub energy harvesting coil and notifying the terminal that there is no electromotive force induced in both energy harvesting coils.

3. The distribution board with wireless leakage and overheating alarm functions enabling an emergency situation to be handled according to claim 2,
wherein the emergency situation control unit is further configured to notify the terminal that an emergency situation has occurred when energy harvested from the main energy harvesting coil is compared with energy harvested from the sub energy harvesting coil and a difference bet ween the energies is a predetermined value or higher.

4. The distribution board with wireless leakage and overheating alarm functions enabling an emergency situation to be handled according to claim 3,
wherein the emergency situation control unit is further configured to cut off power supplied to the conductors to be monitored if an emergency situation has occurred.

5. The distribution board with wireless leakage and overheating alarm functions enabling an emergency situation to be handled according to claim 4,
wherein the emergency power unit is a rechargeable battery or a disposable battery.

6. The distribution board with wireless leakage and overheating alarm functions enabling an emergency situation to be handled according to claim 1,
wherein each of the conductors to be monitored is a quadrangular busbar or a round cable.

7. The distribution board with wireless leakage and overheating alarm functions enabling an emergency situation to be handled according to claim 1,
wherein the conductors to be monitored are either underground cables or overhead power transmission lines.
